(19) United States
(12) Patent Application Publication
(10) Pub. No.: US 2015/0188496 A1
(43) Pub. Date: Jul. 2, 2015

(54) GATE BIAS CONTROL CIRCUIT AND POWER AMPLIFYING DEVICE HAVING THE SAME

(71) Applicant: SAMSUNG ELECTRO-MECHANICS CO., LTD., Suwon-Si (KR)

(72) Inventor: Gyu Suck KIM, Suwon-Si (KR)

(73) Assignee: SAMSUNG ELECTRO-MECHANICS CO., LTD., Suwon-Si (KR)

(21) Appl. No.: 14/281,769

(22) Filed: May 19, 2014

(30) Foreign Application Priority Data
Dec. 30, 2013 (KR) 10-2013-0167664

(51) Int. Cl. H03F 1/02; H03F 3/21

(52) U.S. Cl. CPC H03F 1/0227; H03F 3/21

(57) ABSTRACT

A gate bias control circuit may includes a signal input unit connected to an input terminal of a power amplifier to receive an input signal from the power amplifier, a rectifying unit rectifying the input signal when the input signal has a voltage higher than a preset reference voltage, and a voltage regulating unit regulating a bias voltage of the power amplifier according to a level of the rectified input signal from the rectifying unit.

### CROSS-REFERENCE TO RELATED APPLICATION

This application claims the benefit of Korean Patent Application No. 10-2013-0167664 filed on Dec. 30, 2013, with the Korean Intellectual Property Office, the disclosure of which is incorporated herein by reference.

### BACKGROUND

The present disclosure relates to a gate bias control circuit and a power amplifying device having the same.

In general, wireless communication schemes comprise digital modulation and demodulation schemes, and an appropriate scheme is employed for enhancements in frequency usage efficiency.

For example, cellular phones based on a code division multiple access (CDMA) scheme employ quadrature phase shift keying (QPSK), while wireless local area networks (WLAN) conforming to the Institute of Electrical and Electronics Engineers (IEEE) 802.11 standards employ a digital modulation scheme of orthogonal frequency division multiplexing (OFDM).

Wireless communications systems employing wireless communications schemes commonly include power amplifiers to amplify the power of transmission signals.

A system requiring linear amplification requires a power amplifier having linearity to amplify a transmission signal without distortion. Here, linearity means that even in the case in which the power of an input signal fluctuates, the power of an output signal is amplified by a predetermined ratio and a phase thereof is not changed.

In order to enhance linearity and increase efficiency at a low power point, in a related art power amplifier, an active bias circuit is applied to a base of the power amplifier to change a bias to Class B to reduce a quiescent current at a low power point and change a bias to Class A to increase linearity at a high power point.

However, the related art power amplifier may have relatively complicated circuits and large amounts of required components, thus occupying a relatively large area.

Thus, a gate bias control circuit capable of effectively improving stability and linearity at a high output point by minimizing phase variations between input and output signals, while minimizing circuit complexity and circuit areas is urgently required.

### SUMMARY

An exemplary embodiment in the present disclosure may provide a gate bias control circuit capable of improving maximum linear output power and linear characteristics by varying a gate bias voltage according to an input signal, and a power amplifying device having the same.

According to an exemplary embodiment in the present disclosure, a gate bias control circuit may include: a signal input unit connected to an input terminal of a power amplifier to receive an input signal from the power amplifier; a rectifying unit rectifying the input signal when the input signal has a voltage higher than a preset reference voltage; and a voltage regulating unit regulating a bias voltage of the power amplifier according to a level of the rectified input signal from the rectifying unit.

The signal input unit may include a first capacitor filtering noise from the input signal.

The rectifying unit may include a diode-connected metal-oxide semiconductor field effect transistor (MOSFET), and receive the input signal by a source thereof.

The voltage regulating unit may generate a voltage through a charging or discharging operation according to the rectified input signal and provide the generated voltage to a gate of the power amplifier.

The voltage regulating unit may include a second capacitor performing charging or discharging according to the rectified input signal.

According to an exemplary embodiment in the present disclosure, a gate bias control circuit may include: a first capacitor connected to an input terminal of a power amplifier and filtering noise from an input signal provided by the input terminal; a diode-connected metal-oxide semiconductor field effect transistor (MOSFET) receiving the input signal by a source thereof, and rectifying the input signal when the input signal has a voltage higher than a preset reference voltage; and a second capacitor providing a voltage, generated by charging electric charges according to the rectified input signal, to a gate of the power amplifier.

According to an exemplary embodiment in the present disclosure, a power amplifying device may include: a power amplifier amplifying an input signal upon receiving bias power; and a gate bias control circuit connected to an input terminal of the power amplifier to receive the input signal, rectifying the input signal according to a level of the input signal, and providing a voltage, generated through a charging or discharging operation according to the rectified input signal, to a gate of the power amplifier.

The gate bias control circuit may include: a signal input unit connected to the input terminal of the power amplifier to receive the input signal from the power amplifier; a rectifying unit rectifying the input signal when the input signal has a voltage higher than a preset reference voltage; and a voltage regulating unit regulating a bias voltage of the power amplifier according to a level of the rectified input signal from the rectifying unit.

The signal input unit may include a first capacitor filtering noise from the input signal.

The rectifying unit may include a diode-connected metal-oxide semiconductor field effect transistor (MOSFET), and receive the input signal by a source thereof.

The voltage regulating unit may generate the voltage through the charging or discharging operation according to the rectified input signal and provide the generated voltage to the gate of the power amplifier.

The voltage regulating unit may include a second capacitor performing the charging or discharging operation according to the rectified input signal.

The power amplifying device may further include an input matching circuit unit matching impedance on a signal transmission path between the input terminal of the power amplifier and the power amplifier.

The power amplifying device may further include an output matching circuit unit matching impedance on a signal transmission path between an output terminal to which an output signal amplified by the power amplifier is output and the power amplifier.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a configuration of a power amplifying device according to an exemplary embodiment of the present disclosure;

FIG. 2 is a block diagram illustrating a configuration of a power amplifier illustrated in FIG. 1;

FIG. 3 is a block diagram illustrating a configuration of an example of a gate bias control circuit illustrated in FIG. 1;

FIG. 4 is a block diagram illustrating a configuration of another example of the gate bias control circuit illustrated in FIG. 1;

FIG. 5 is a graph illustrating a gate bias voltage provided by the gate bias control circuit of FIG. 3;

FIG. 6 is a graph illustrating an average power level of a gate bias provided to a power amplifier by the gate bias control circuit of FIG. 3; and

FIG. 7 is a graph illustrating a power gain of the power amplifier output according to an average power level of a gate bias provided to the power amplifier by the gate bias control circuit of FIG. 6.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

Throughout the drawings, the same or like reference numerals will be used to designate the same or like elements.

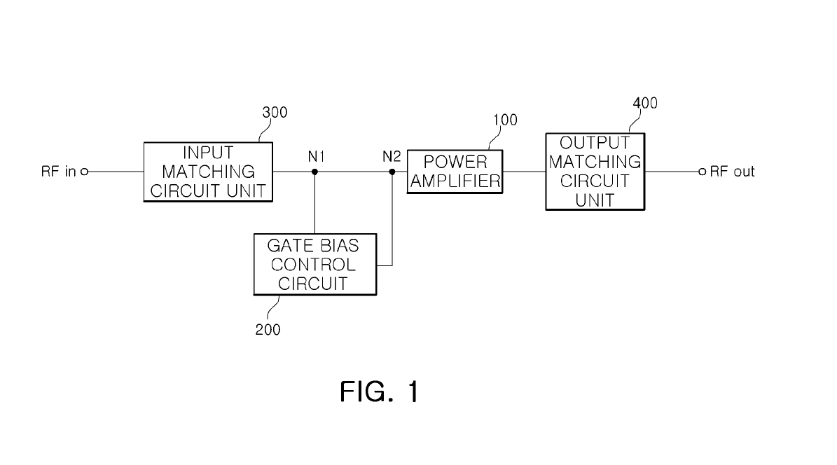

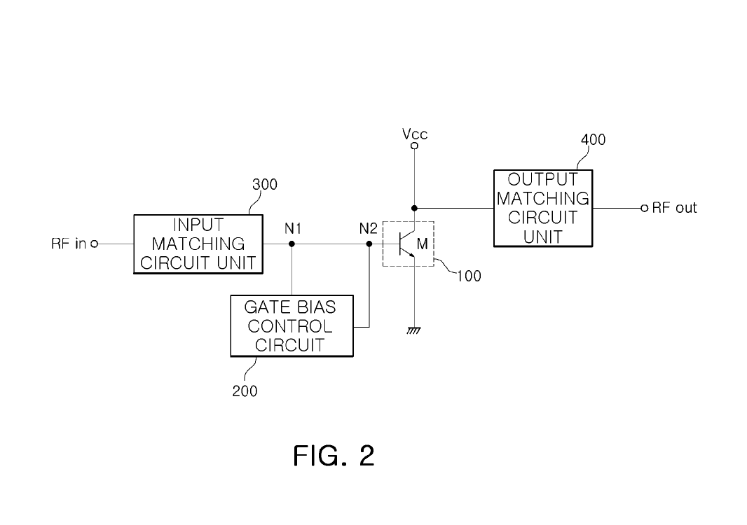

FIG. 1 is a block diagram illustrating a configuration of a power amplifying device according to an exemplary embodiment of the present disclosure, and FIG. 2 is a block diagram illustrating a configuration of a power amplifier illustrated in FIG. 1.

Referring to FIG. 1, the power amplifying device according to this exemplary embodiment of the present disclosure may include a power amplifier 100 and a gate bias control circuit 200.

Here, the power amplifying device may further include an input matching circuit unit 300 connected to an input terminal. Also, the power amplifying device may further include an output matching circuit unit 400 connected to an output terminal.

As illustrated in FIG. 2, the power amplifier 100 may include an amplifying transistor M.

An input signal to be amplified may be input to a base of the amplifying transistor M, and bias power from the gate bias control circuit 200 may be supplied thereto.

A collector of the amplifying transistor M may receive driving power Vcc from an input terminal, and may output an amplified signal.

An emitter of the amplifying transistor M may be connected to a ground.

The gate bias control circuit 200 may provide a voltage generated according to an average power level of an RF input signal RF in received from an input terminal of the power amplifier 100, to the power amplifier 100.

In detail, the gate bias control circuit 200 may be connected to the input terminal of the power amplifier 100 to receive an input signal, rectify the input signal according to a level thereof, and provide a voltage generated through a charging or discharging operation according to the rectified input signal to a gate of the power amplifier.

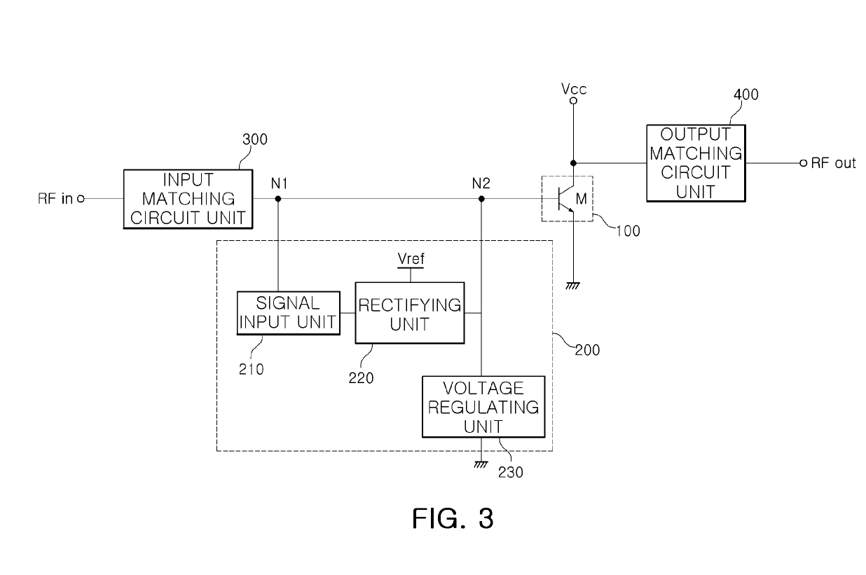

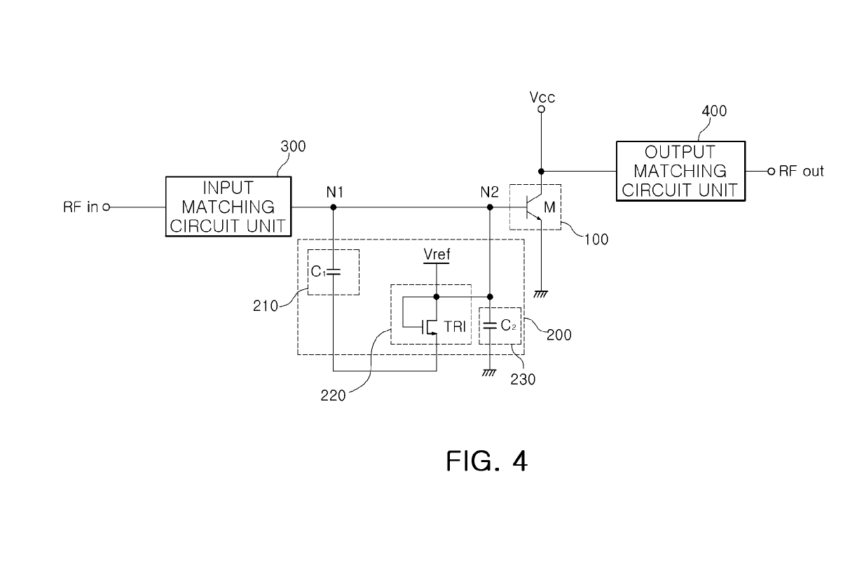

The gate bias control circuit 200 will be described in detail with reference to FIGS. 3 and 4.

Meanwhile, the power amplifying device according to the present exemplary embodiment may further include the input matching circuit unit 300 matching impedance on a signal transmission path between an input terminal providing an input signal to the power amplifier 100 and the power amplifier 100, and the output matching circuit unit 400 matching impedance on a signal transmission path between an output terminal to which an output signal amplified by the power amplifier 100 is output and the power amplifier 100.

In detail, the input matching circuit unit 300 may be positioned between the base of the amplifying transistor M and the input terminal to match impedance on a signal transmission path.

The output matching circuit unit 400 may be positioned between the collector of the amplifying transistor M and the output terminal to match impedance on a signal transmission path.

FIG. 3 is a block diagram illustrating a configuration of an example of the gate bias control circuit illustrated in FIG. 1, and FIG. 4 is a block diagram illustrating a configuration of another example of the gate bias control circuit illustrated in FIG. 1.

Referring to FIG. 3, the gate bias control circuit 200 according to the exemplary embodiment of the present disclosure may include a signal input unit 210, a rectifying unit 220, and a voltage regulating unit 230.

The signal input unit 210 may be connected to the input terminal of the power amplifier 100 to receive the RF input signal RF in from the power amplifier 100.

In the exemplary embodiment, as illustrated in FIG. 4, the signal input unit 210 may include a first capacitor C₁ filtering noise from the RF input signal RF in.

Here, the first capacitor C₁ may have a capacity required for blocking noise. Also, the first capacitor C₁ may interrupt a direct current (DC) signal.

Thus, the signal input unit 210 may provide only a pure RF input signal among signals input from the input terminal to the power amplifier 100, to the rectifying unit 220.

The rectifying unit 220 may rectify the RF input signal provided by the signal input unit 210. Here, the rectifying unit 220 may rectify the RF input signal only when the RF input signal has a voltage higher than a preset reference voltage.

In the exemplary embodiment, the rectifying unit 220 may be configured as a rectifying element or a rectifying circuit such as a diode.

Also, as illustrated in FIG. 4, the rectifying unit 220 may include a diode-connected metal-oxide semiconductor field effect transistor (MOSFET). In this case, the RF input signal provided by the signal input unit 210 may be input to a source of the diode-connected MOSFET.

The voltage regulating unit 230 may regulate a bias voltage of the power amplifier 100 according to a level of the rectified RF input signal from the rectifying unit 220.

In the exemplary embodiment, the voltage regulating unit 230 may generate a voltage through a charging or discharging operation according to a level of the rectified RF input signal from the rectifying unit 220. In this case, as illustrated in FIG. 4, the voltage regulating unit 230 may include a second capacitor C2 performing the charging or discharging operation according to the rectified RF input signal.

Here, since the second capacitor C2 performs charging according to the rectified RF input signal, if an input voltage of the RF input signal is increased, an average voltage level is increased. Thus, a gate bias voltage of the power amplifier 100 is increased according to the RF input signal.

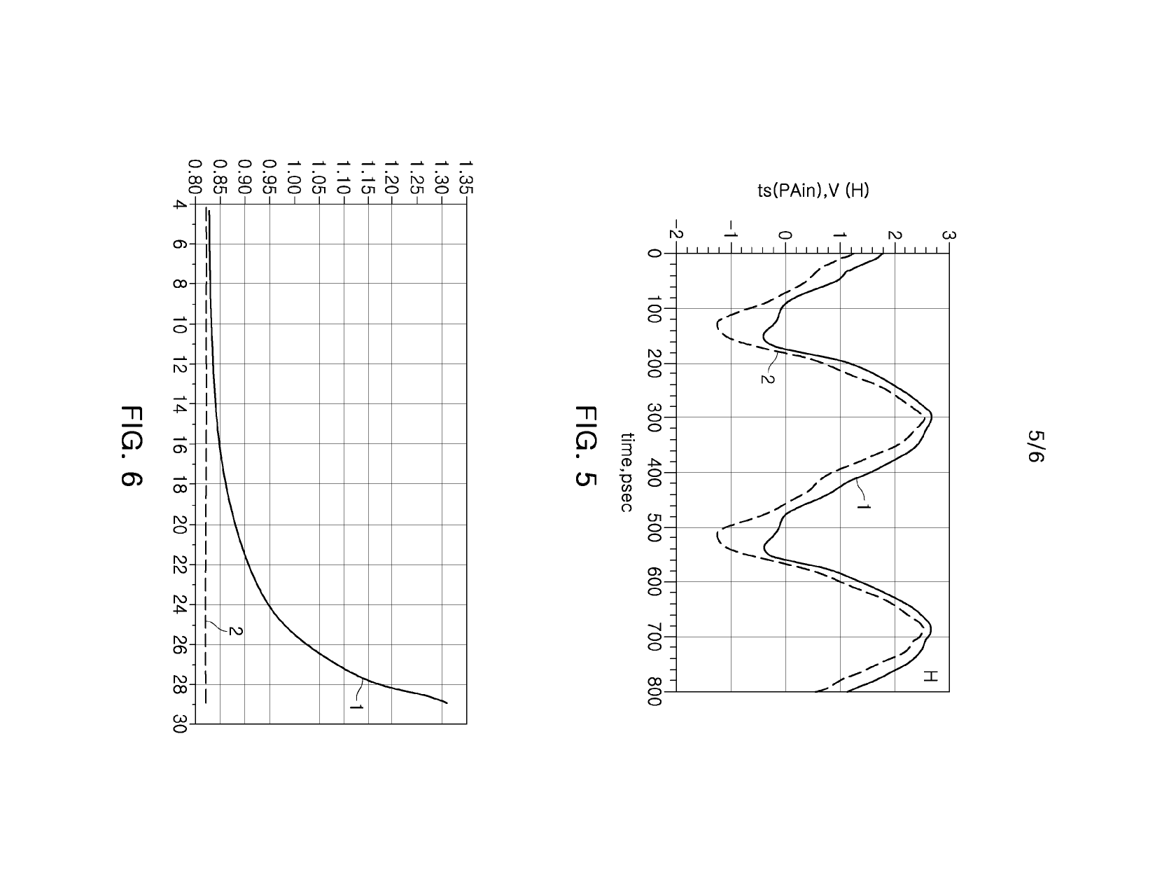

FIG. 5 is a graph illustrating a gate bias voltage provided by the gate bias control circuit of FIG. 3.

Referring to FIG. 5, it can be seen that, as compared to a gate bias voltage 2 in the case of a power amplifier without a gate bias control circuit, an average voltage level of a gate bias voltage 1 provided by the gate bias control circuit 200 is increased according to an increase in an input signal.

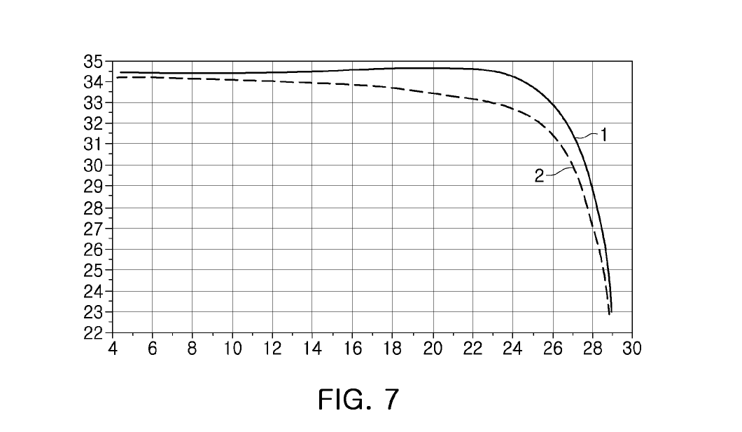

FIG. 6 is a graph illustrating an average power level of a gate bias provided to the power amplifier by the gate bias control circuit of FIG. 3, and FIG. 7 is a graph illustrating a power gain of the power amplifier output according to an average power level of a gate bias provided to the power amplifier by the gate bias control circuit of FIG. 6.

Referring to FIG. 6, in case (2) in which the gate bias control circuit 200 is not provided, an average power level of a gate bias provided to the power amplifier is maintained as a constant voltage irrespective of a power level of an input signal. Thus, in this case, as illustrated in FIG. 7, in a power gain output from the power amplifier 100, a maximum linear output power point may be lowered as output power is increased.

In contrast, in case (1) in which the gate bias control circuit 200 is provided, an average power level of a gate bias provided to the power amplifier 100 may be increased as a power level of an input signal is increased. Thus, in this case, as illustrated in FIG. 7, a maximum linear output of a power gain output from the power amplifier 100 maybe uniformly maintained to the vicinity of a maximum output power point. Namely, the maximum linear output section may be improved, and in the exemplary embodiment, the maximum linear output section may be improved by 3 dB or greater.

As set forth above, in a power amplifying device according to exemplary embodiments of the present disclosure, output efficiency at a low power point may be improved and linearity at a high power point may be enhanced by varying a gate bias voltage according to an input signal.

While exemplary embodiments have been shown and described above, it will be apparent to those skilled in the art that modifications and variations could be made without departing from the spirit and scope of the present disclosure as defined by the appended claims.

What is claimed is:

1. A gate bias control circuit, comprising:
a signal input unit connected to an input terminal of a power amplifier to receive an input signal from the power amplifier;
a rectifying unit configured to rectify the input signal when the input signal has a voltage higher than a preset reference voltage; and
a voltage regulating unit configured to regulate a bias voltage of the power amplifier according to a level of the rectified input signal from the rectifying unit.

2. The gate bias control circuit of claim 1, wherein the signal input unit includes a first capacitor filtering noise from the input signal.

3. The gate bias control circuit of claim 1, wherein the rectifying unit includes a diode-connected metal-oxide semiconductor field effect transistor (MOSFET), and receives the input signal by a source thereof.

4. The gate bias control circuit of claim 1, wherein the voltage regulating unit generates a voltage through a charging or discharging operation according to the rectified input signal and provides the generated voltage to a gate of the power amplifier.

5. The gate bias control circuit of claim 4, wherein the voltage regulating unit includes a second capacitor generating the voltage by charging or discharging electric charges according to the rectified input signal.

6. A gate bias control circuit, comprising:
a first capacitor connected to an input terminal of a power amplifier and filtering noise from an input signal provided by the input terminal;
a diode-connected metal-oxide semiconductor field effect transistor (MOSFET) configured to receive the input signal by a source thereof, and rectify the input signal when the input signal has a voltage higher than a preset reference voltage; and
a second capacitor configured to provide a voltage, generated by charging electric charges according to the rectified input signal, to a gate of the power amplifier.

7. A power amplifying device, comprising:
a power amplifier configured to amplify an input signal upon receiving bias power; and
a gate bias control circuit connected to an input terminal of the power amplifier to receive the input signal, configured to rectify the input signal according to a level of the input signal, and provide a voltage, generated through a charging or discharging operation according to the rectified input signal, to a gate of the power amplifier.

8. The power amplifying device of claim 7, wherein the gate bias control circuit includes:
a signal input unit connected to the input terminal of the power amplifier to receive the input signal from the power amplifier;
a rectifying unit configured to rectify the input signal when the input signal has a voltage higher than a preset reference voltage; and
a voltage regulating unit configured to regulate a bias voltage of the power amplifier according to a level of the rectified input signal from the rectifying unit.

9. The power amplifying device of claim 8, wherein the signal input unit includes a first capacitor filtering noise from the input signal.

10. The power amplifying device of claim 8, wherein the rectifying unit includes a diode-connected metal-oxide semiconductor field effect transistor (MOSFET), and receives the input signal by a source thereof.

11. The power amplifying device of claim 8, wherein the voltage regulating unit generates the voltage through the charging or discharging operation according to the rectified input signal and provides the generated voltage to the gate of the power amplifier.

12. The power amplifying device of claim 11, wherein the voltage regulating unit includes a second capacitor performing the charging or discharging operation according to the rectified input signal.

13. The power amplifying device of claim 8, further comprising an input matching circuit unit configured to match impedance on a signal transmission path between the input terminal of the power amplifier and the power amplifier.

14. The power amplifying device of claim 8, further comprising an output matching circuit unit configured to match impedance on a signal transmission path between an output terminal to which an output signal amplified by the power amplifier is output and the power amplifier.
